(19) United States
(12) Patent Application Publication
(10) Pub. No.: US 2013/0056733 A1
(43) Pub. Date: Mar. 7, 2013

(54) SENSOR AND METHOD OF PRODUCING A SENSOR

(71) Applicants: Holger Vogt, Muehlheim (DE); Dirk Weiler, Herne (DE); Piotr Kropelnicki, Woodgorve Condominium (SG)

(72) Inventors: Holger Vogt, Muehlheim (DE); Dirk Weiler, Herne (DE); Piotr Kropelnicki, Woodgorve Condominium (SG)

(21) Appl. No.: 13/594,520

(22) Filed: Aug. 24, 2012

(30) Foreign Application Priority Data
Aug. 26, 2011 (DE) 102011081641.0

(51) Int. Cl. H01L 31/036; H01L 31/18; H01L 31/0376

(52) U.S. Cl. 257/53; 257/431; 257/290; 438/64; 257/E31.047; 257/E31.04

(57) ABSTRACT

A sensor includes a substrate, a membrane, first and second spacers arranged on the substrate, a first support structure which is supported, laterally next to the membrane, by the first spacer and contacts a first electrode of a first main side of the membrane which faces the substrate, and a second support structure which is supported, laterally next to the membrane, by the second spacer and contacts a second electrode on a second main side of the membrane which is opposite the first main side, so that the membrane is suspended via the first and second spacers and is electrically connected to contact areas of the substrate.

### CROSS-REFERENCE TO RELATED APPLICATIONS

This application claims priority from German Patent Application No. 102011081641.0 which was filed on Aug. 26, 2011, and is incorporated herein in its entirety by reference.

### TECHNICAL FIELD

Embodiments of the invention relate to a sensor and a method of producing a sensor. Further embodiments of the invention relate to contacting of monocrystalline optical sensors.

### BACKGROUND OF THE INVENTION

Detection of infrared radiation is becoming increasingly important in many different fields. For the automobile industry, this importance lies in achieving increased safety for, e.g., pedestrians, who can be made visible with infrared sensors even in dark surroundings. If an automatic brake system is coupled to a sensor system, accidents may be avoided, or their impacts may at least be attenuated. Further applications of infrared sensors include, e.g., inspecting technical equipment (e.g. electric lines or even printed circuit boards) or buildings. In the future, medical applications may also become relevant. Even today, infrared sensors are being employed in the field of surveillance of buildings and sites and in border control.

For many of said applications, the achievable resolution of minimum temperature differences is an important quality criterion of the measurement instrument used. In commercial devices, said sensitivity is mostly indicated as NETD (Noise Equivalent Temperature Difference), and in uncooled bolometers, temperature difference values of, e.g., less than 100 mK are achieved. The notation of said characteristic parameter immediately illustrates the internal limitation of sensors, which is due to the noise properties of the system used. For example, if one uses, as a detector material, a thin membrane as a sensor, which membrane heats up under the influence of infrared radiation and changes its electric resistance in the process, the electric noise properties of said system will determine which resistance (and, thus, temperature) changes can still be detected and be separated from the noise background. If the change in the resistance of the material which is induced by the change in temperature is smaller than the noise of the electric parameters, it will no longer be resolved.

In many homogeneous amorphous sensor materials (such as silicon, vanadium oxide, etc.) the change in resistance, expressed as a percentage, is proportional to the change in temperature. The proportionality constant is essentially defined by the choice of the material and by the process parameters, its optimization generally being bound by tight limits. Typical values of the change in resistance range from about 2 to 3% per K.

As far as the change in resistance is defined by the material properties of the sensor, there still remain two further essential possibilities of influencing the sensor properties to a relatively large extent. A first possibility consists in making the sensor elements as large as possible. The larger the surface area available for the sensor and for the associated thermal insulation areas, the more radiation can be absorbed, or the more radiation energy will be converted to an increase in temperature of the sensor. This approach has the decisive disadvantage that it cannot accommodate the increasing desire for miniaturization and, thus, reduction in the price of the devices.

If the goal consists in optimizing the signal/noise ratio at a constant overall size for cost reasons, another approach that remains is the possibility of minimizing the noise. There are different noise sources in electronic devices. In amorphous materials, the so-called 1/f noise, wherein the noise power density is inversely proportional to the frequency f, will typically be predominant. This is a serious problem in that the integrative readout circuits (low pass) typically used are not suited to suppress the predominant low-frequency components of said noise.

One possibility of circumventing this problem consists in using monocrystalline material such as silicon, for example. In said materials, the 1/f noise is typically not predominant, and a good signal/noise ratio may be achieved by integrating the measurement signal. However, this advantage typically is at the expense of a heavily reduced dependence of the resistance on the temperature. For example, the temperature dependence of the resistance may have a value of 0.3% per K.

For this reason it may be advantageous to also use such monocrystalline diodes, transistors and quantum well structures as IR sensors which comprise low 1/f noise while having high temperature coefficients. However, integration of such thermally insulated sensors in a CMOS process involves quite some effort. The initially used approach of producing the insulated diodes directly in the CMOS wafer by suitable undercutting etching processes has the disadvantage of requiring a very large amount of surface area without combining useful insulation and absorption properties.

### SUMMARY

According to an embodiment, a sensor may have: a substrate; a membrane; first and second spacers arranged on the substrate; a first support structure which is supported, laterally next to the membrane, by the first spacer and contacts a first electrode of a first main side of the membrane which faces the substrate; and a second support structure which is supported, laterally next to the membrane, by the second spacer and contacts a second electrode on a second main side of the membrane which is opposite the first main side, so that the membrane is suspended via the first and second spacers and is electrically connected to contact areas of the substrate.

According to another embodiment, a method of producing a sensor may have the steps of: providing a first wafer having a carrier substrate and a patterned membrane layer which is arranged on the carrier substrate and is provided to be included in a membrane of the sensor, and having a first support structure contacting a first electrode on a first main side of the membrane layer which faces away from the carrier substrate and extending laterally away from the membrane layer; providing a second wafer including a substrate; bonding the first wafer and the second wafer by means of a bonding material; removing the carrier substrate so that the second main side of the membrane layer which is opposite the first main side is exposed; applying a second support structure so that same contacts a second electrode on a second main side, which is opposite the first main side, of the membrane layer and extends laterally away from the membrane layer; forming second spacers carrying the first and second support structures laterally next to the membrane in each case; and removing the bonding material.

Embodiments of the present invention provide a sensor comprising a substrate, a membrane, first and second spacers, a first support structure and a second support structure. Here, the first and second spacers are arranged on the substrate. The first support structure is supported, laterally next to the membrane, by the first spacer and contacts a first electrode on a first main side of the membrane which faces the substrate. The second support structure is supported, laterally next to the membrane, by the second spacer and contacts a second electrode on a second main side of the membrane which is opposite the first main side. In this manner, the membrane can be suspended via the first and second spacers and be electrically connected to contact areas of the substrate.

The core idea of the present invention is that the above-mentioned improved area utilization and increased sensitivity and/or the more flexible or precise readout may be achieved when providing a first support structure which is supported, laterally next to the membrane, by the first spacer and contacts a first electrode on a first main side of the membrane which faces the substrate, and a second support structure which is supported, laterally next to the membrane, by the second spacer and contacts a second electrode on a second main side of the membrane which is opposite the first main side. Thus, the membrane can be suspended via the first and second spacers and be electrically connected to the contact areas of the substrate. Moreover, in this manner, the membrane cannot be contacted laterally only, but also vertically. This results in that the 1/f noise may be avoided or at least suppressed. Thus, area utilization may be improved and sensitivity may be increased, on the one hand, and more flexible or more precise readout may thereby be achieved, on the other hand.

In further embodiments of the present invention, the membrane comprises a p-n junction extending in parallel with a surface of the substrate, so that the p-n junction is serially connected between the contact areas of the substrate.

In further embodiments of the present invention, the sensor further comprises a readout circuit configured to alternately operate the p-n junction in the forward direction in a first working cycle and in the reverse direction in a second working cycle. In this manner, any incident IR radiation may be detected in the first working cycle, and any incident UV and/or white light radiation may be detected in the second working cycle.

In further embodiments of the present invention, the sensor further comprises third and fourth electrodes, the first to fourth electrodes being arranged at a distance from one another along a forward direction on a respective one of the first and second main sides of the membrane. The sensor here further comprises a readout circuit configured to generate, via a first pair of the first to fourth electrodes which have the largest distance from each other among the first to fourth electrodes along the forward direction, a predetermined current flow and to detect a voltage between a second pair of the first to fourth electrodes which are located between the first pair in the forward direction. Thus, a four-position measurement may be realized with which a resistance and/or a change in the resistance of the membrane may be measured with very high precision.

In further embodiments of the present invention, the membrane comprises a vertical bipolar transistor or a field-effect transistor. With such structures, a captured signal may be amplified directly at the membrane and/or at the sensor element, so that the extension of a readout circuit, at least part of which is arranged, within the substrate, laterally between the first and second spacers, may be considerably reduced.

Further embodiments of the present invention provide a method of producing a sensor. The method includes the following steps, for example. Initially, a first wafer having a carrier substrate and a patterned membrane layer, which is arranged on the carrier substrate and provided to be included in a membrane of the sensor, and having a first support structure which contacts a first electrode on a first main side, which faces away from the carrier substrate, of the membrane layer and extends laterally away from the membrane layer, is provided. Subsequently, a second wafer having a substrate is provided. Then the first wafer and the second wafer are bonded by means of a bonding material. Then the carrier substrate is removed, so that the second main side of the membrane layer, which is opposite the first main side, is exposed. Then a second support structure is applied, so that same contacts a second electrode on a second main side of the membrane layer, which is opposite the first main side, and extends laterally away from the membrane layer. Subsequently, two spacers are formed which carry the first and second support structures laterally next to the membrane in each case. Finally, the bonding material is removed. By means of such a production method, vertical contacting of the membrane and/or of the sensor element may be achieved.

### BRIEF DESCRIPTION OF THE DRAWINGS

Embodiments of the present invention will be detailed subsequently referring to the appended drawings, in which:

FIG. 1 shows a cross-sectional view of a sensor in accordance with an embodiment of the present invention;

FIG. 2 shows a cross-sectional view of a sensor having a p-n junction in accordance with a further embodiment of the present invention;

FIG. 3 shows a cross-sectional view of a sensor for a four-position measurement in accordance with a further embodiment of the present invention;

FIG. 4 shows a cross-sectional view of a sensor having a vertical bipolar transistor in accordance with a further embodiment of the present invention;

FIG. 5 shows a cross-sectional view of a sensor having a field-effect transistor in accordance with a further embodiment of the present invention;

FIGS. 6a-6d show cross-sectional views for illustrating an inventive provision of a sensor wafer;

FIG. 7 shows a cross-sectional view for illustrating inventive bonding of a sensor wafer to a substrate wafer by means of a bonding material; and

FIGS. 8a-8c show cross-sectional views for illustrating inventive processing of sensor and substrate wafers that are bonded to each other.

### DETAILED DESCRIPTION OF THE INVENTION

Before the present invention will be explained in more detail below by means of the figures, it shall be pointed out that in the embodiments presented in the following, elements which are identical or identical in function are provided with the identical reference numerals in the figures. Therefore, descriptions of elements having identical reference numerals are mutually exchangeable and/or mutually applicable in the various embodiments.

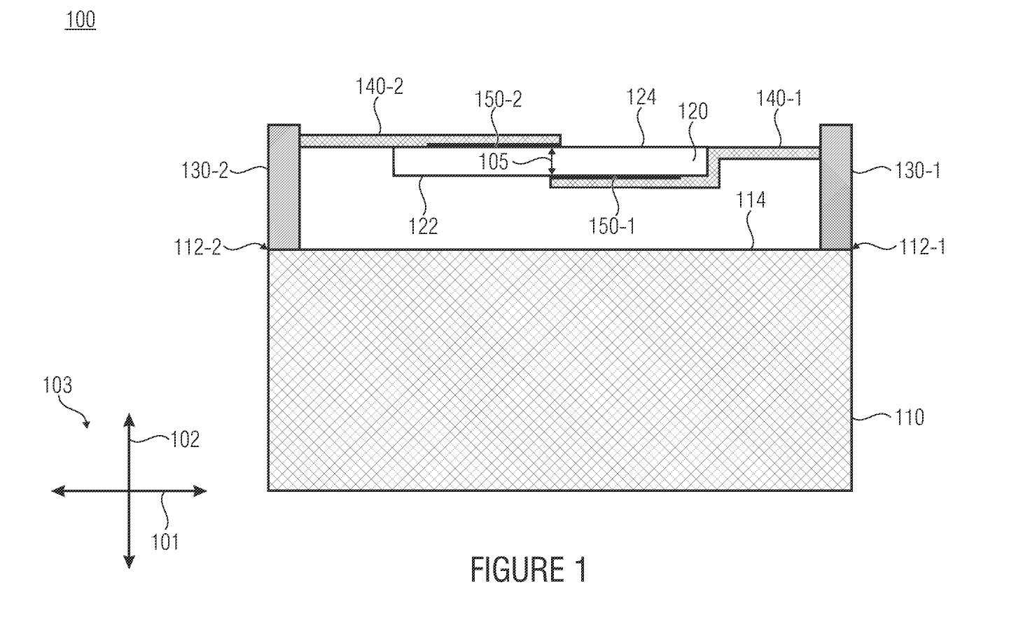

FIG. 1 shows a cross-sectional view of a sensor 100 in accordance with an embodiment of the present invention. As is shown in FIG. 1, the sensor 100 comprises a substrate 110, a membrane 120, first and second spacers 130-1, 130-2, a first support structure 140-1 and a second support structure 140-2. Here, the first and second spacers 130-1, 130-2 are arranged on the substrate 110. In the sensor 100 shown in FIG. 1, the first support structure 140-1 is supported, laterally next to the membrane 120, by the first spacer 130-1 and contacts a first electrode 150-1 on a first main side 122 of the membrane 120 which faces the substrate 110. In addition, the second support structure 140-2 is supported, laterally next to the membrane 120, by the second spacer 130-2 and contacts a second electrode 150-2 on a second main side 124 of the membrane 120 which is opposite the first main side 122. Thus, in the embodiment of FIG. 1, the membrane 120 may be suspended via the first and second spacers 130-1, 130-2 and be electrically connected to contact areas 112-1, 112-2 of the substrate 110.

In further embodiments, the membrane 120 of the sensor 100 may comprise a semiconductor layer having a monocrystalline material or having an amorphous material.

Moreover, the sensor 100 shown in FIG. 1 may comprise a readout circuit (not shown), at least part of the readout circuit being arranged, within the substrate 110, laterally between the first and second spacers 130-1, 130-2.

In the embodiment shown in FIG. 1, the sensor 100 may be an optical sensor such as a bolometer, for example, or an electro(mechanical) sensor such as a sensor based on a mechanical resonator, for example.

By means of the vertical contacting, shown in FIG. 1, of the two opposite main sides 122, 124 of the membrane 120 via the first and second electrodes 150-1, 150-2, a current flow having an essentially vertical flow direction (vertical current flow direction) may be generated. In FIG. 1, a horizontal direction corresponds to a direction parallel to a first axis 101 of a coordinate system 103, whereas a vertical direction corresponds to a direction parallel to a second axis 102 of the coordinate system 103. Here, the first axis 101 of the coordinate system 103 is defined as an axis parallel to a surface of the substrate 110, whereas the second axis 102 of the coordinate system 103 is defined as an axis perpendicular to the surface of the substrate 110. The essentially vertical forward (flow) direction thus is parallel to the second axis 102 of the coordinate system 103 and is indicated by an arrow 105 located between the two opposite main sides 122, 124 of the membrane 120.

In the embodiment shown in FIG. 1, the membrane 120 of the sensor 100 may consist of a monocrystalline material, it being possible to generate, via vertical contacting with the first and second electrodes 150-1, 150-2, a current flow having a vertical flow direction through the monocrystalline material. This is advantageous in that the 1/f noise within the monocrystalline material may be avoided or at least suppressed, whereby the electrical noise properties of the sensor may be considerably improved.

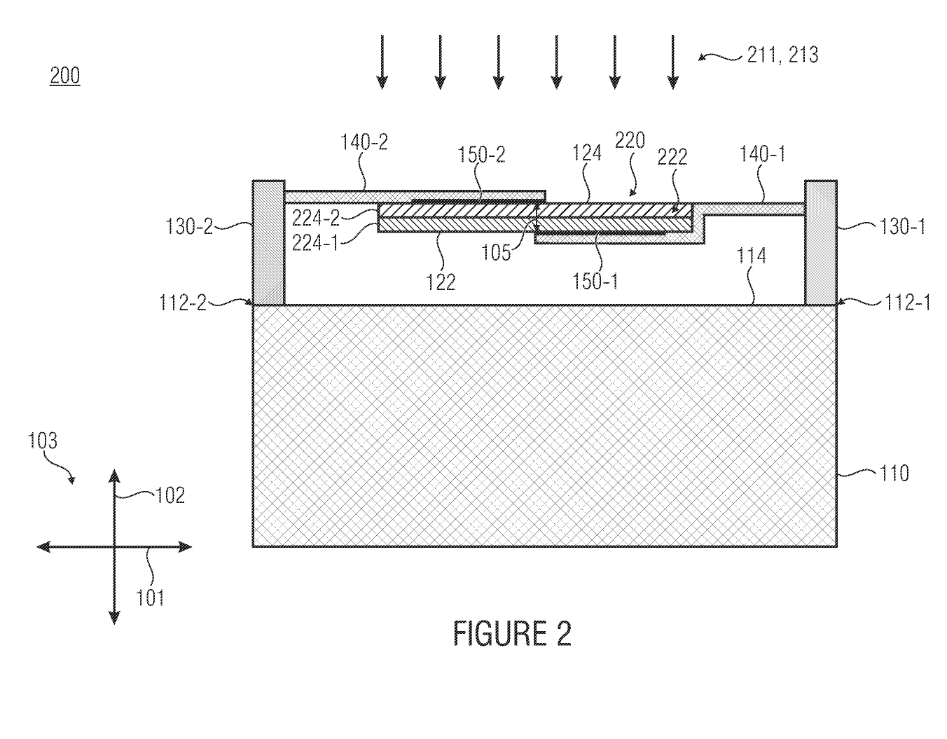

FIG. 2 shows a cross-sectional view of a sensor 200 comprising a p-n junction in accordance with a further embodiment of the present invention. Here, the sensor 200 having a membrane 220 in FIG. 2 essentially corresponds to the sensor 100 having the membrane 120 in FIG. 1. In the embodiment shown in FIG. 2, the membrane 220 of the sensor 200 has a p-n junction 222. As is shown in FIG. 2, the p-n junction 222 extends in parallel with a surface of the substrate 110. FIG. 2, in turn, shows the coordinate system 103 of FIG. 1, the first and second axes 101, 102 of the coordinate system 103 being parallel and perpendicular to the surface of the substrate 110, respectively. The p-n junction 222 of the membrane 220 thus is parallel to the first axis 101 of the coordinate system 103.

In the embodiment of FIG. 2, the membrane 220 comprises complementarily doped semiconductor layers 224-1, 224-2. The complementarily doped semiconductor layers 224-1, 224-2 may be p-doped or n-doped semiconductor layers, for example, which form the p-n junction 222. With reference to FIG. 2, the complementarily doped semiconductor layers 224-1, 224-2 are arranged such that the p-n junction 222 is serially connected between the contact areas 112-1, 112-2 of the substrate 110. As in the sensor 100 shown in FIG. 1, in the sensor 200 shown in FIG. 2, both opposite main sides 122, 124 of the membrane 220 may be contacted, via the first and second electrodes 150-1, 150-2, such that a current flow having an essentially vertical flow direction (arrow 105) may be generated (vertical contacting). The essentially vertical flow direction here is parallel to the second axis 102 of the coordinate system 103.

In embodiments of FIG. 2, the sensor 200 further comprises a readout circuit (not shown) configured to operate the p-n junction 222 in the forward direction to detect any incident IR (infrared) radiation 211. Thus, the sensor 200 may be, e.g., an infrared sensor based on a diode in the forward operation and/or on a p-n junction operated in the forward direction. Here, the infrared sensor may be sensitive to incident IR radiation having an IR wavelength, which is typically to be detected, of, e.g. 10 μm or up to an IR wavelength, which is maximally to be detected, of e.g. 14 μm (IR detection).

In further embodiments of FIG. 2, the sensor 200 further comprises a readout circuit configured to operate the p-n junction 222 in the reverse direction to detect any incident UV (ultraviolet) and/or white light radiation 213. Thus, the sensor 200 may be, e.g., a UV/white light sensor based on a diode in the reverse operation and/or on a p-n junction operated in the reverse direction. Here, the UV/white light sensor may be sensitive to incident UV and/or white light radiation up to a minimally to be detected UV wavelength of, e.g., 300 nm (UV/white light detection).

In further embodiments of FIG. 2, the readout circuit of the sensor 200 may be configured to alternatingly operate the p-n junction 222 in the forward direction in a first working cycle and in the reverse direction in a second working cycle so as to detect any incident IR radiation 211 in the first working cycle, and to detect any incident UV and/or white light radiation 213 in the second working cycle. Thus, the sensor 200 may be a multiwavelength sensor, for example, based on a p-n junction (diode) alternatingly operated in the forward and reverse directions. By means of said multiwavelength sensor, alternating detection of IR radiation and UV/white light radiation may be enabled, for example.

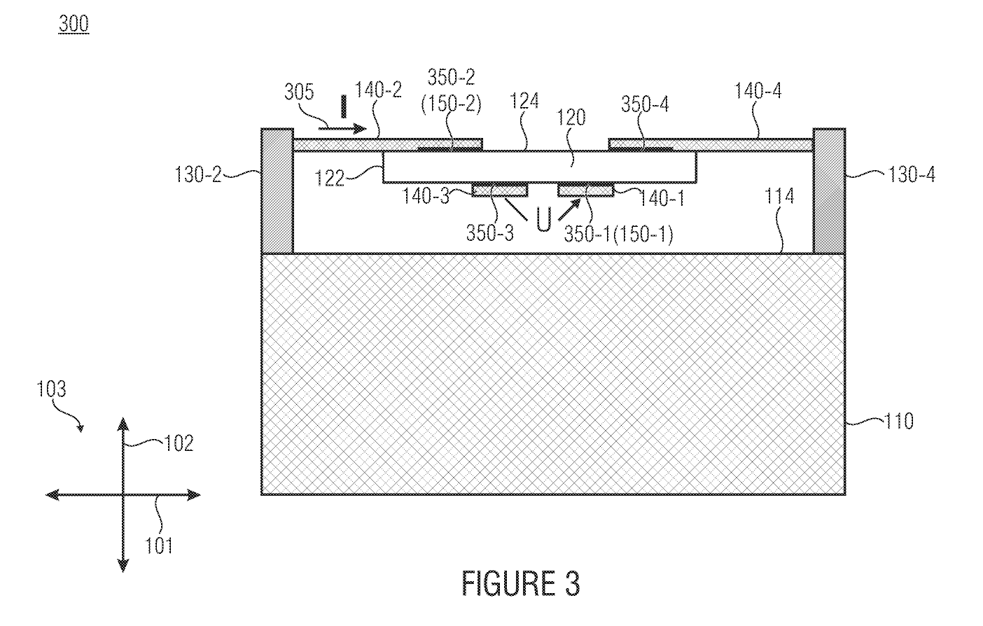

FIG. 3 shows a cross-sectional view of sensor 300 for a four-position measurement in accordance with a further embodiment of the present invention. The sensor 300 having the first and second electrodes 350-1, 350-2 in FIG. 3 essentially corresponds to the sensor 100 having the first and second electrodes 150-1, 150-2 in FIG. 1. Moreover, the sensor 300 comprises third and fourth spacers (130-4), third and fourth support structures 140-3, 140-4, and third and fourth electrodes 350-3, 350-4. The first and third spacers are not shown in the cross-sectional view of FIG. 3. With reference to FIG. 3, the first to fourth electrodes 350-1, 350-2, 350-3, 350-4 are arranged along a forward direction 305 on a respective one of the first and second main sides 122, 124 of the membrane 120 such that they are spaced apart from one another. FIG. 3 again shows the coordinate system of FIG. 1, the first and second axes 101, 102 being parallel and perpendicular to the surface of the substrate 110, respectively. The forward direction 305, along which the first to fourth electrodes 350-1, 350-2, 350-3, 350-4 are arranged, essentially corresponds to a current flow direction of a current (I) in parallel with the first axis 101 of the coordinate system 103. the third and fourth spacers are arranged on the substrate 110. In addition, the third support structure 140-3 is supported, laterally next to the membrane 120, by the third spacer and contacts the third electrode 350-3, whereas the fourth support structure 140-4 is supported, laterally next to the membrane 120, by the fourth spacer and contacts the fourth electrode 350-4.

In the embodiment shown in FIG. 3, the readout circuit of the sensor 300 is configured to generate, via a first pair 350-2, 350-4 of the first to fourth electrodes 350-1, 350-2, 350-3, 350-4 which have the largest distance from each other among the first to fourth electrodes 350-1, 350-2, 350-3, 350-4 along the forward direction 305, a predetermined current flow I and to detect a voltage U between a second pair 350-1, 350-3 of the first to fourth electrodes 350-1, 350-2, 350-3, 350-4 which are located between the first pair 350-2, 350-4 in the forward direction 305. By generating the predetermined current flow I via the (outer) first pair 350-2, 350-4 and by detecting the voltage U between the (inner) second pair 350-1, 350-3, one may realize a four-position measurement for accurately determining the electrical resistance of the membrane 120.

In other words, by means of the sensor 300 shown in FIG. 3, a four-position measurement based on multiple contacting of the membrane 120 may be enabled. For example, the four electrodes 350-1, 350-2, 350-3, 350-4 may be arranged on the membrane in a series, it being possible for a known current I to be impressed via the two outer electrodes 350-2, 350-4, whereas a voltage drop U at the membrane and/or at the sensor element may be measured via the two inner electrodes 350-1, 350-3. On the basis of the voltage drop U measured and of the known current I, the resistance of the membrane and/or of the sensor element may be determined with very high precision. Thus, the resistance or the change in resistance of the sensor element may be accurately determined by means of said multiple contacting of the sensor element (four-position measurement).

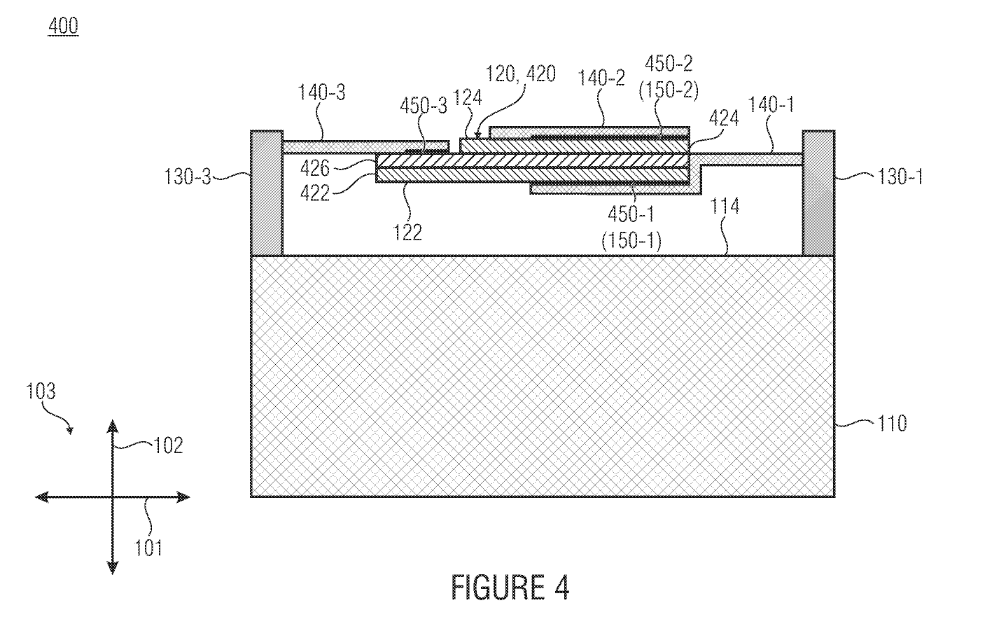

FIG. 4 shows a cross-sectional view of a sensor 400 having a vertical bipolar transistor in accordance with a further embodiment of the present invention. The sensor 400 comprising the first and second electrodes 450-1, 450-2 in FIG. 4 essentially corresponds to the sensor 100 having the first and second electrodes 150-1, 150-2 in FIG. 1. In the embodiment shown in FIG. 4, the sensor 400 further comprises a third spacer 130-3, a third support structure 140-3 and a third electrode 450-3, the third spacer 130-3 being arranged on the substrate 110. The second spacer is not shown in the cross-sectional view of FIG. 4. The third support structure 140-3 is supported, laterally next to the membrane 120, by the third spacer 130-3 and contacts the third electrode 450-3.

In the embodiment shown in FIG. 4, the membrane 120 of the sensor 400 comprises a vertical bipolar transistor 420 having emitter, collector and base terminals 450-1, 450-2, 450-3 (or emitter, collector and base 422, 424, 426). Emitter, collector and base 422, 424, 426 of the vertical bipolar transistor 420 may form, e.g., a first transistor structure (p-n-p transistor) having two p-doped semiconductor layers (emitter and collector 422, 424) and an intermediate n-doped semiconductor layer (base 426), or a second transistor structure (n-p-n transistor) having two n-doped semiconductor layers (emitter and collector 422, 424) and an intermediate p-doped semiconductor layer (base 426). In the first transistor structure, p-n junctions are formed by one of the p-doped semiconductor layers and by the n-doped semiconductor layer, respectively, whereas in the second transistor structure, the p-n junctions are formed by one of the n-doped semiconductor layers and by the p-doped semiconductor layer. As is shown in FIG. 4, the first and second electrodes 450-1, 450-2 form the emitter and collector terminals 450-1, 450-2, respectively. Moreover, the third electrode 450-3 of the sensor 400 forms the base terminal 450-3.

By means of the sensor 400 shown in FIG. 4, a vertical bipolar transistor 420 thus is implemented, the vertical bipolar transistor 420 being suspended, via the first to third spacers, above a readout circuit located within the substrate 110, and being electrically connected to associated contact areas of the substrate 110. By means of the vertical contacting of the emitter, the collector and the base 422, 424, 426 in accordance with the embodiment shown in FIG. 4, a signal which has been captured or is to be detected may be directly amplified at the vertical bipolar transistor 420 suspended above the readout circuit, and/or at the sensor element. It is therefore possible to reduce the essentially lateral extension of the readout circuit, whereby improved area utilization and/or a more compact design may be achieved while increasing the sensitivity of the sensor at the same time.

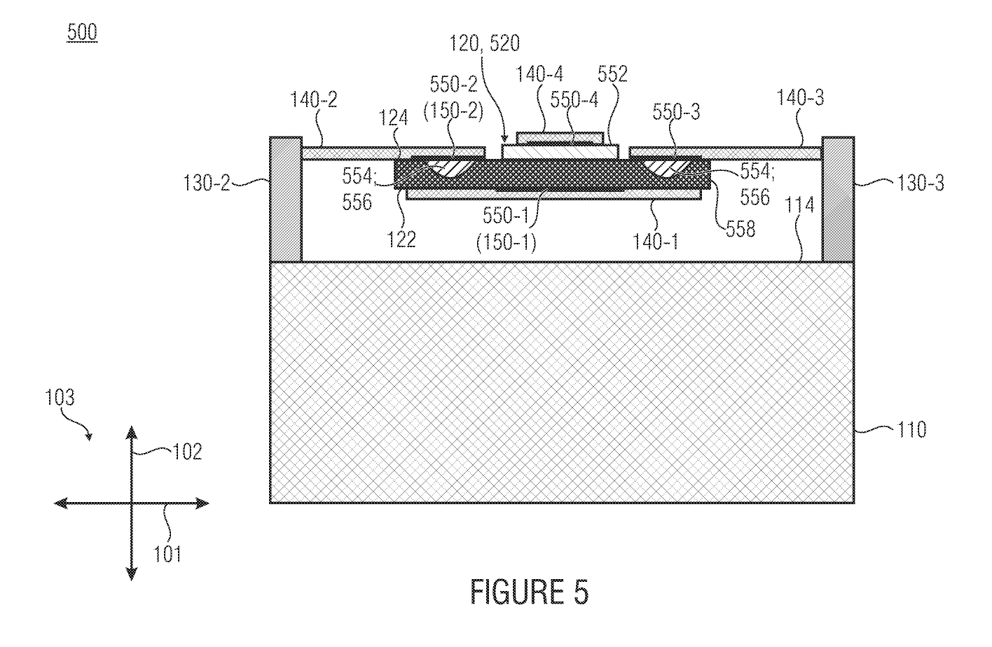

FIG. 5 shows a cross-sectional view of a sensor 500 having a field-effect transistor in accordance with a further embodiment of the present invention. The sensor 500 having the first and second electrodes 550-1, 550-2 in FIG. 5 essentially corresponds to the sensor 100 having the first and second electrodes 150-1, 150-2 in FIG. 1. In the embodiment of FIG. 5, the sensor 500 further comprises a third spacer 130-3 and a fourth spacer, third and fourth support structures 140-3, 140-4, and third and fourth electrodes 550-3, 550-4. The first and fourth spacers are not shown in the cross-sectional view of FIG. 5. The third spacer 130-3 and the fourth spacer are arranged on the substrate 110. In addition, the third support structure 140-3 is supported, laterally next to the membrane 120, by the third spacer 130-3 and contacts the third electrode 550-3, whereas the fourth support structure 140-4 is supported, laterally next to the membrane 120, by the fourth spacer and contacts the fourth electrode 550-4.

In the embodiment shown in FIG. 5, the membrane 120 of the sensor 500 comprises a field-effect transistor 520 having gate, drain, source and bulk terminals 550-4, 550-2, 550-3, 550-1 (or gate, drain, source and bulk 552, 554, 556, 558). The first and second electrodes 550-1, 550-2 each form a different one from the bulk terminal 550-1, on the one hand, and the gate, drain and source terminals 550-4, 550-2, 550-3, on the other hand. In addition, the other ones of the gate, drain and source terminals 550-4, 550-2, 550-3 are formed by the third and fourth electrodes 550-3, 550-4.

Gate, drain, source and bulk 552, 554, 556, 558 of the field-effect transistor 520 may form, e.g., a first transistor structure (NMOS transistor, n-type metal-oxide semiconductor transistor) having two n-doped semiconductor areas (source and drain 554, 556), an interposed p-doped semiconductor area (bulk 558) and an insulating layer located on the p-doped semiconductor area (gate 552), or a second transistor structure (PMOS transistor, p-channel metal-oxide semiconductor transistor) having two p-doped semiconductor areas (source and drain 554, 556), an interposed n-doped semiconductor area (bulk 558) and an insulating layer located on the n-doped semiconductor area (gate 552). In embodiments of FIG. 5, the first transistor structure may be configured to provide an n-channel during operation of same. Thus, e.g. an re-channel field-effect transistor may be implemented by means of the first transistor structure. In further embodiments of FIG. 5, the second transistor structure may be configured to provide a p-channel during operation of same. Thus, e.g. a p-channel field-effect transistor may be implemented by means of the second transistor structure.

The sensor 500 shown in FIG. 5 may be a MOSFET (metal-oxide semiconductor field-effect transistor), for example. Here, the MOSFET may be suspended, via the first to fourth spacers, above a readout circuit located within the substrate 110, and may be electrically connected to associated contact areas of the substrate 110. By means of the contacting via the gate, drain, source and bulk terminals of the MOSFET in accordance with the embodiment shown in FIG. 5, a measurement signal captured by the MOSFET may be amplified directly at the MOSFET suspended above the readout circuit, so that it is possible to reduce the essentially lateral extension of the readout circuit. Similarly to the embodiment shown in FIG. 4, area utilization may thus be improved while increasing the sensitivity of the sensor.

With reference to FIGS. 4 and 5, transistor structures such as a bipolar transistor (FIG. 4) or a MOSFET (FIG. 5) may thus be provided which are characterized in that the measurement signal captured may be amplified directly at the respective transistor structure (sensor element), and therefore, the readout circuit and/or amplifier circuit within the substrate may have a more compact design.

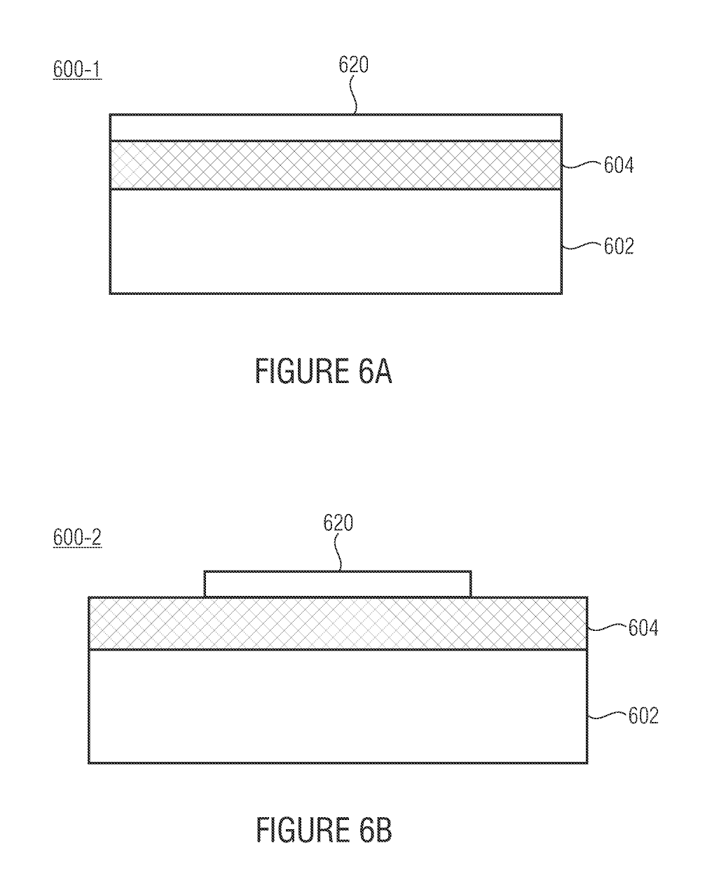

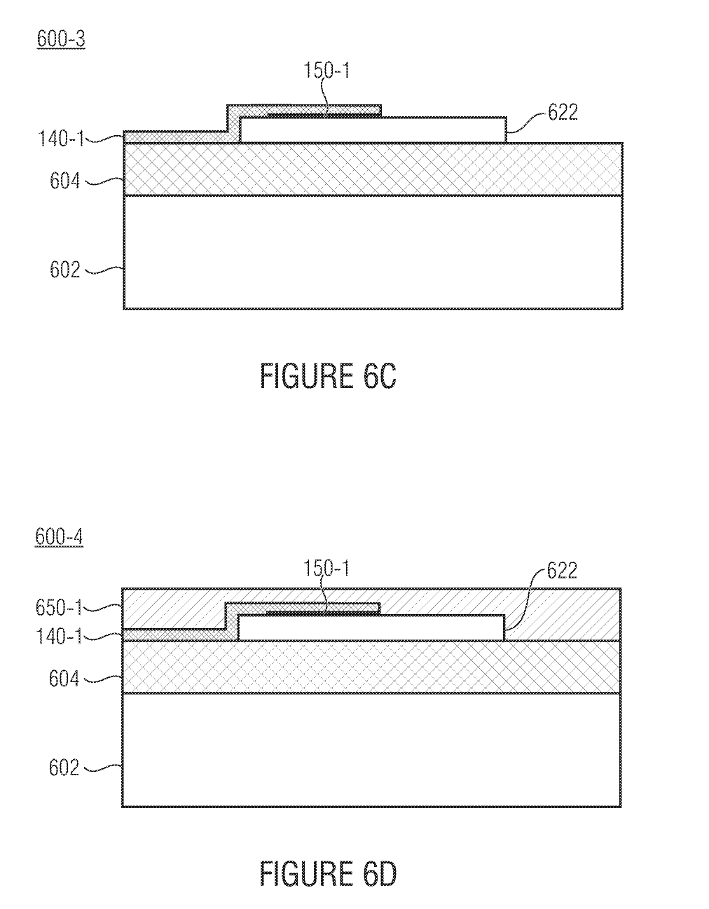

FIGS. 6a to 6d show cross-sectional views for illustrating inventive provision of a sensor wafer. By way of example, FIGS. 6a to 6d show a sequence of processes for providing the sensor wafer, the sensor wafer having a patterned membrane layer provided to be included in a membrane of the sensor.

FIG. 6a shows an SOI (silicon on insulator) wafer 600-1 by way of example. The SOI wafer 600-1 shown in FIG. 6a may be used as a basis for providing the sensor wafer. With reference to FIG. 6a, the SOI wafer 600-1 comprises, e.g., an SOI substrate 602, a membrane layer 620 and an interposed oxide layer 604. Here, the membrane layer 620 may be a semiconductor layer having a monocrystalline material (e.g. silicon), for example, which is separated from the SOI substrate 602, such as a silicon substrate, by a buried oxide layer, such as a BOX (buried oxide) layer, for example. The membrane layer 620, which is present in the form of a monocrystalline silicon layer, for example, serves as a foundation for an active sensor layer of the sensor to be produced. Instead of the SOI wafer, other semiconductor wafers may alternatively also be used for the sequence of processes shown in FIGS. 6a to 6d.

By way of example, FIG. 6b shows how a modified SOI wafer 600-2 is obtained in a subsequent step. The modified SOI wafer 600-2 shown in FIG. 6b comprises a patterned membrane layer 622, for example, which is produced by patterning the membrane layer 620 of the SOI wafer 600-1 shown in FIG. 6a.

By way of example, FIG. 6c shows how a further modified SOI wafer 600-3 is obtained in a further subsequent step. The further modified SOI wafer 600-3 shown in FIG. 6c may be produced by initially applying a first electrode 150-1 to the patterned membrane layer 622 of the SOI wafer 600-2 shown in FIG. 6b. As is shown in FIG. 6c, a first support structure 140-1 is subsequently applied, so that same contacts the first electrode 150-1 and extends laterally away from the patterned membrane layer 622.

By way of example, FIG. 6d shows how the sensor wafer 600-4 is finally obtained in a further subsequent step. The sensor wafer 600-4 shown in FIG. 6d may be provided by applying a first bonding layer 650-1 to the patterned membrane layer 622 and to the first support structure 140-1. The sensor wafer 600-4 provided with the first bonding layer 650-1 represents a first wafer for a subsequent bonding process.

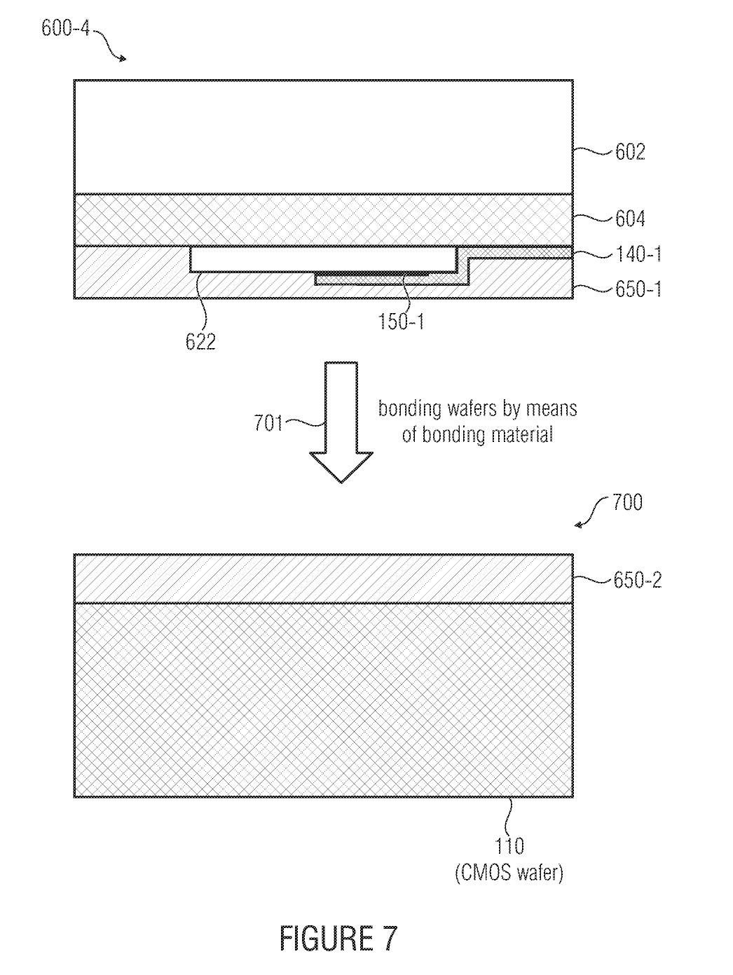

FIG. 7 shows a cross-sectional view for illustrating inventive bonding of a sensor wafer to a substrate wafer by means of a bonding material. FIG. 7 shows a first wafer 600-4 (sensor wafer) and a second wafer 700 (substrate wafer). Here, the first wafer 600-4 is identical to the sensor wafer provided in FIG. 6d. The second wafer 700 in FIG. 7 comprises a substrate 110 (CMOS wafer).

In addition, the second wafer 700 shown in FIG. 7 comprises a second bonding layer 650-2 above the substrate 110. As is indicated by the arrow 701, the first wafer 600-4 and the second wafer 700 may be bonded by means of a bonding material in that the first bonding layer 650-1 of the first wafer 600-4 is bonded to the second bonding layer 650-2 of the second wafer 700. Said bonding, shown in FIG. 7, of the sensor wafer to the substrate wafer is effected, e.g., on the basis of wafer-to-wafer bonding. The wafers bonded in accordance with the bonding process of FIG. 7 represent a starting structure for further process steps.

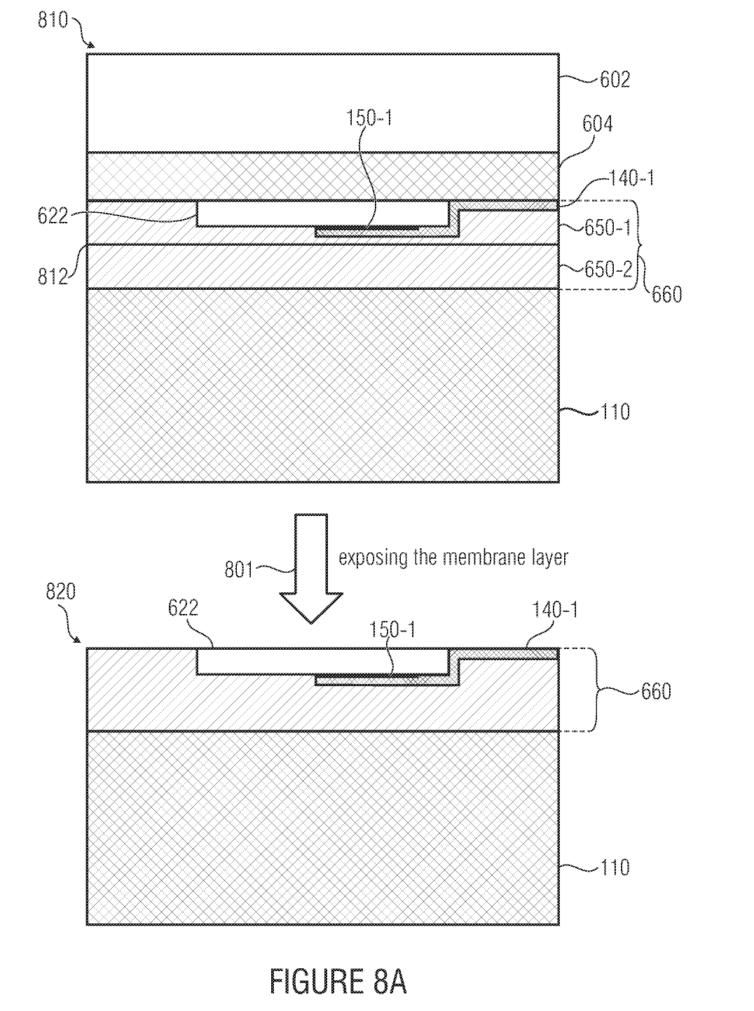

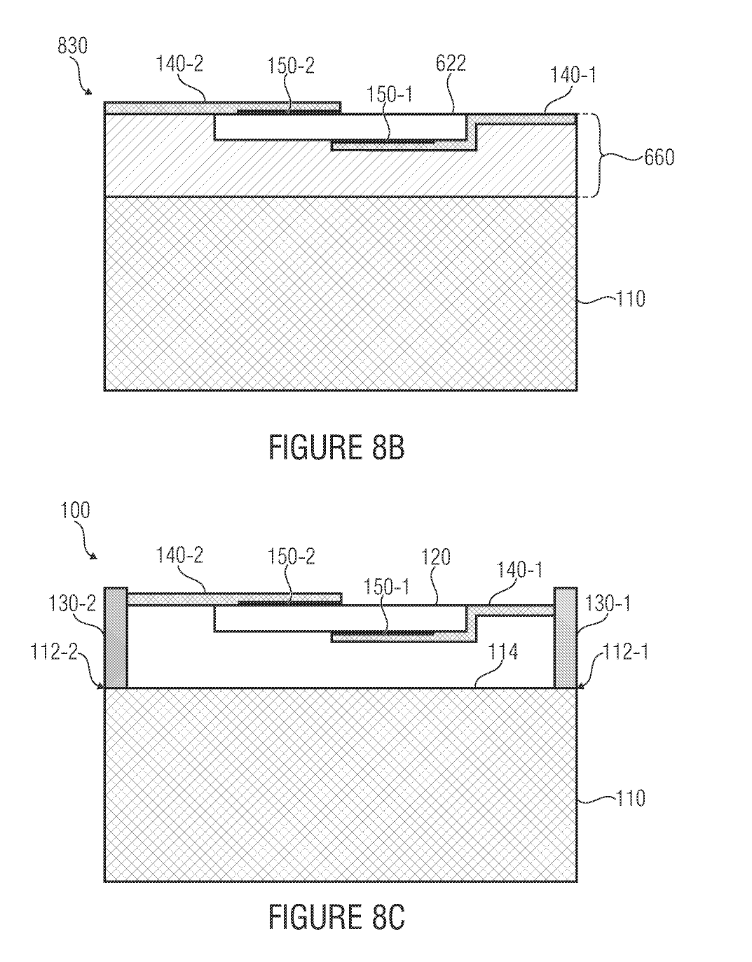

FIGS. 8a to 8c show cross-sectional views for illustrating inventive processing of sensor and substrate wafers that are bonded to each other. FIG. 8a shows the starting structure 810 obtained following the bonding process of FIG. 7. The starting structure 810 shown in FIG. 8a comprises, e.g., a layer sequence comprising the SOI substrate 602, the oxide layer 604, the patterned membrane layer 622, the first electrode 150-1, the first support structure 140-1, the first and second bonding layers 650-1, 650-2, and the substrate 110 (carrier substrate). Here, the first and second bonding layers 650-1, 650-2 form an area 660 comprising a bonding material, a bonding surface 812 being located between the first and second bonding layers 650-1, 650-2. The bonding surface 812 is shown only in the cross-sectional view of the starting structure 810 and is not shown in the cross-sectional views for illustrating the further process steps.

FIG. 8a further illustrates exemplary exposure of the patterned membrane layer 622 in a further subsequent step (arrow 801). Exposing the patterned membrane layer 622 here is based on the starting structure 810 formed by the sensor and substrate wafers bonded to each other. The patterned membrane layer 622 may be exposed in that, e.g., upper layers of the starting structure 810 which may no longer be used (e.g. the SOI substrate 602 and the oxide layer 604) are removed by abrasion or by selective etching. Once the patterned membrane layer 622 has been exposed, the modified structure 820 shown in FIG. 8a thus results. As is shown in FIG. 8a, the modified structure 820 comprises the exposed membrane layer 622, which is arranged on the bonding area 660 above the substrate 110.

FIG. 8b shows how a further modified structure 830, based on the modified structure 820 shown in FIG. 8a, is obtained in a further subsequent step. The further modified structure 830 shown in FIG. 8b comprises a second electrode 150-2 arranged on the patterned membrane layer 622, and a second support structure 140-2 contacting the second electrode 150-2 and extending laterally away from the (exposed) patterned membrane layer 622. To obtain the further modified structure 830 of FIG. 8b, the second electrode 150-2 and the second support structure 140-2 may be applied, e.g. one after the other, to the patterned membrane layer 622. This enables the patterned membrane layer 622 to be contacted from two opposite sides of same via the first and second electrodes 150-1, 150-2. In further embodiments, a further intermediate layer may be applied to the patterned membrane layer 622 prior to application of the second electrode 150-2, so that the second electrode 150-2 will adjoin a side of the membrane layer 622 or a side of the intermediate layer.

FIG. 8c shows how finally, the sensor 100 of FIG. 1 is obtained in a further subsequent step. The sensor 100 shown in FIG. 8c may be obtained, e.g., in that two spacers 130-1, 130-2 are formed which carry the first and second support structures 140-1, 140-2 laterally next to the membrane 120 in each case. Formation of the second spacers may be performed, e.g., in that openings extending onto contact areas 112-1, 112-2 of the substrate 110 are formed initially by an etching process through the first and second support structures 140-1, 140-2 and the bonding area 660, and in that the openings provided are subsequently filled with a conductive material (e.g. a metal). Finally, the bonding material of the bonding area 660 may be removed, for example by means of etching, so that the sensor 100 comprises the membrane 120, which may be suspended via the first and second spacers 130-1, 130-2 and be electrically connected to the contact areas 112-1, 112-2 of the substrate 110.

With reference to the previous figures (FIGS. 6a to 6d, 7 and 8a to 8c), a method of producing a sensor (e.g. sensor 100 in FIG. 1) thus includes the following steps, for example. In a first process step, a first wafer 600-4 is provided (see FIG. 6d). The first wafer 600-4 comprises a carrier substrate 602, a patterned membrane layer 622, a first electrode 150-1 and a first support structure 140-1. The patterned membrane layer 622 is arranged on the carrier substrate 602 and is provided to be included in a membrane 120 of the sensor 100. The first support structure 140-1 contacts the first electrode 150-1 on a first main side, which faces away from the carrier substrate 602, of the membrane layer 622 and extends laterally away from the membrane layer 622. Provision of the first wafer 600-4 may include producing a semiconductor layer 620 with a monocrystalline material or an amorphous material. Moreover, provision of the first wafer 600-4 may be performed such that same is an SOI wafer. Here, the membrane layer 622 may be a monocrystalline silicon layer of the SOI wafer, for example, which is separated from an SOI substrate 602 of the SOI wafer by a buried oxide layer 604.

In further process steps, the first wafer 600-4 and a second wafer 700 provided, which comprises a substrate 110, may be connected by means of a bonding material (FIG. 7). Here, the second wafer 700 may be provided in that, e.g., a wafer having a readout circuit is produced, at least part of the readout circuit being provided within the substrate 110.

In a further process step, the carrier substrate 602 is removed, so that the second main side of the membrane layer 622 which is opposite the first main side is exposed (FIG. 8a). In a further process step, a second support structure 140-2 is applied, so that same contacts a second electrode 150-2 on a second main side, which is opposite the first main side, of the membrane layer 622 and extends laterally away from the membrane layer 622 (FIG. 8b). Here, the second electrode 150-2 may adjoin the second main side of the membrane layer 622 or a side of a previously applied intermediate layer.

In further process steps, two spacers 130-1, 130-2, which carry the first and second support structures 140-1, 140-2 laterally next to the membrane 120 in each case, are formed, and the bonding material is finally removed (FIG. 8c).

In further embodiments, the above-described method may further comprise applying a first bonding layer 650-1 to the patterned membrane layer 622 and providing the second wafer 700 such that same comprises a second bonding layer 650-2. Then, the first and second wafers 600-4, 700 (sensor and substrate wafers) may be connected by bonding the first bonding layer to the second bonding layer 650-1, 650-2.

Thus, with the inventive method, production of, e.g., bonded IR sensors having a vertical design and improved electrical and optical properties may be enabled. Briefly summarized, the production may include the following steps, for example.

Initially, a wafer (substrate wafer) comprising a readout circuit (readout integrated circuit, ROIC) is produced. In those areas where the electrical contact to the sensor wafer will be made later on, said wafer comprises contact areas. Next, the sensor wafer, for example based on SOI technology or a technology providing a thin active semiconductor layer, is produced (FIG. 6a). Here, at first the active semiconductor layer is patterned (FIG. 6b), followed by contacting of the semiconductor layer by a future support structure (FIG. 6c). In addition, a bonding layer (FIG. 6d) is produced, and the actual bonding process takes place (FIG. 7). In a further step, the active layer (patterned membrane layer 622), which now is located on a rear side or on a main side of the membrane layer 622 which faces away from the substrate 110, is exposed (FIG. 8a), and again is contacted from the rear side and/or from above with an additional support structure (FIG. 8b). Subsequently, contacting of the sensor structure (membrane 120) with the circuit wafer and/or the substrate wafer takes place, and the last step comprises etching the membrane such that it is exposed (FIG. 8c).

Even though some aspects have been described within the context of a device, it is understood that said aspects also represent a description of the corresponding method, so that a block or a structural component of a device is also to be understood as a corresponding method step or as a feature of a method step. By analogy therewith, aspects that have been described in connection with or as a method step also represent a description of a corresponding block or detail or feature of a corresponding device. Some or all of the method steps may be performed while using a hardware device, such as a microprocessor, a programmable computer or an electronic circuit. In some embodiments, some or several of the most important method steps may be performed by such a device.

The above-described embodiments merely represent an illustration of the principles of the present invention. It is understood that other persons skilled in the art will appreciate any modifications and variations of the arrangements and details described herein. This is why the invention is intended to be limited only by the scope of the following claims rather than by the specific details that have been presented herein by means of the description and the discussion of the embodiments.

Embodiments of the present invention provide a possibility of producing the readout circuit and the sensor elements, such as diode or transistor structures, in different wafers and of finally combining the two wafers by means of so called wafer-to-wafer bonding. Said wafer-to-wafer bonding offers the advantage of more flexible contacting of the respective sensor element (e.g. IR sensor). For example, contacting of a monocrystalline sensor and/or of the sensor element may be vertical. By means of vertical contacting, a lower 1/f noise may be obtained since the current flowing through the device is preferably found in monocrystalline material and sees—as compared to, e.g., laterally contacted devices—a smaller interface between, e.g., silicon and silicon dioxide.

Embodiments of the present invention provide a kind of processing with which it is possible to electrically contact IR sensors in a flexible manner and thus to create advantageous properties of the sensor. For example, the IR sensors can be contacted and built not only laterally, but also vertically, the current preferably flowing within the monocrystalline material, and the device exhibiting low 1/f noise.

Embodiments of the present invention provide improved sensors made of monocrystalline or non-monocrystalline material which may be built vertically. As a result, a lower 1/f noise of the devices thus contacted may be obtained.

Further embodiments of the present invention enable multiple contacting of a sensor element and/or device, specifically for four-position measurement.

Further embodiments of the present invention provide sensors having a CMOS circuit located underneath same, optical vertical sensors (within the wavelength range from 300 nm to 14 μm), or multiwavelength sensors for alternating operation within the UV/white light range and the IR range.

Due to the degree of freedom of the contacting of the sensor elements it is possible to produce sensors having improved electrical noise properties. For example, a vertical diode structure in accordance with FIG. 2, the current of which preferably flows through a monocrystalline material, may be produced. In this context, the diode may be used both in the forward operation (IR detection) and in the reverse operation (UV/white light detection), so that a multiwavelength sensor is provided. Moreover, with this contacting, transistor structures such as bipolar transistors in accordance with FIG. 4 of MOSFETS in accordance with FIG. 5 may be provided. The advantage of said structures is that the signal captured may be amplified directly at the sensor element, and that, thus, the amplifier circuit within the CMOS may be minimized.

Another advantageous structure is represented by the sensor in accordance with FIG. 3, which is contacted by means of four-position measurement. In this manner, the resistance and/or a change in resistance of the sensor may be measured with very high precision. In this context, as was described in connection with FIG. 3, a current I is impressed, and the voltage drop U at the sensor element is measured.

Embodiments of the present invention provide a structure in the form of a monocrystalline sensor having a vertical flow direction, and a process flow for producing same. Generally, thus, a monocrystalline sensor having a vertical current flow direction is provided. This may be both an optical and a mechanical sensor, the respective sensor being located above a CMOS circuit.

In accordance with further embodiments, sensors based on an amorphous material and having a vertical current flow direction may be provided.

Further embodiments provide a four-position measurement method for optical sensors so as to be able to determine the resistance of a sensor with very high precision.

Moreover, the vertical contacting of the sensor enables using same as a multiwavelength sensor. For example, a vertical diode may be used in the forward direction as an IR sensor and in the reverse direction as a UV/white light sensor.

Due to said vertical contacting, implementation of a sensor on the basis of a transistor can also be ensured. For example, a monocrystalline bipolar transistor/MOSFET may be provided which may be advantageously produced with vertical contacting.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A sensor comprising:
a substrate;
a membrane;
first and second spacers arranged on the substrate;
a first support structure which is supported, laterally next to the membrane, by the first spacer and contacts a first electrode of a first main side of the membrane which faces the substrate; and
a second support structure which is supported, laterally next to the membrane, by the second spacer and contacts a second electrode on a second main side of the membrane which is opposite the first main side, so that the membrane is suspended via the first and second spacers and is electrically connected to contact areas of the substrate.

2. The sensor as claimed in claim 1, wherein the membrane comprises a semiconductor layer comprising a monocrystalline material or comprising an amorphous material.

3. The sensor as claimed in claim 1, further comprising a readout circuit, at least part of the readout circuit being arranged, within the substrate, laterally between the first and second spacers.

4. The sensor as claimed in claim 1, wherein the membrane comprises a p-n junction extending in parallel with a surface of the substrate, so that the p-n junction is serially connected between the contact areas of the substrate.

5. The sensor as claimed in claim 4, the sensor further comprising a readout circuit configured to operate the p-n junction in the forward direction so as to detect any incident IR radiation.

6. The sensor as claimed in claim 4, the sensor further comprising a readout circuit configured to operate the p-n junction in the reverse direction so as to detect any incident UV and/or white light radiation.

7. The sensor as claimed in claim 4, the sensor further comprising a readout circuit configured to alternatingly operate the p-n junction in the forward direction in a first working cycle and in the reverse direction in a second working cycle so as to detect any incident IR radiation in the first working cycle and any incident UV and/or white light radiation in the second working cycle.

8. The sensor as claimed in claim 1, further comprising third and fourth spacers, third and fourth support structures, and third and fourth electrodes, the first to fourth electrodes being arranged at a distance from one another along a forward direction on a respective one of the first and second main sides of the membrane, the third and fourth spacers being arranged on the substrate, the third support structure being supported, laterally next to the membrane, by the third spacer and contacting the third electrode, and the fourth support structure being supported, laterally next to the membrane, by the fourth spacer and contacting the fourth electrode, the sensor further comprising a readout circuit configured to generate, via a first pair of the first to fourth electrodes which comprise the largest distance from each other among the first to fourth electrodes along the forward direction, a predetermined current flow and to detect a voltage between a second pair of the first to fourth electrodes which are located between the first pair in the forward direction.

9. The sensor as claimed in claim 1, further comprising a third spacer, a third support structure and a third electrode, the third spacer being arranged on the substrate, the third support structure being supported, laterally next to the membrane, by the third spacer and contacting the third electrode, the membrane comprising a vertical bipolar transistor comprising emitter, collector and base terminals, the first and second electrodes forming the emitter and collector terminals, respectively, and the third electrode forming the base terminal.

10. The sensor as claimed in claim 1, further comprising third and fourth spacers, third and fourth support structures, and third and fourth electrodes, the third and fourth spacers being arranged on the substrate, the third support structure being supported, laterally next to the membrane, by the third spacer and contacting the third electrode, and the fourth support structure being supported, laterally next to the membrane, by the fourth spacer and contacting the fourth electrode, the membrane comprising a field-effect transistor comprising gate, drain, source and bulk terminals, the first and second electrodes each forming a different one from the bulk terminal, on the one hand, and the gate, drain, and source terminals, on the other hand, the other ones of the gate, drain and source terminals being formed by the third and fourth electrodes.

11. A method of producing a sensor, comprising:
providing a first wafer comprising a carrier substrate and a patterned membrane layer which is arranged on the carrier substrate and is provided to be comprised by a membrane of the sensor, and comprising a first support structure contacting a first electrode on a first main side of the membrane layer which faces away from the carrier substrate and extending laterally away from the membrane layer;
providing a second wafer comprising a substrate;
bonding the first wafer and the second wafer by means of a bonding material;
removing the carrier substrate so that the second main side of the membrane layer which is opposite the first main side is exposed;
applying a second support structure so that same contacts a second electrode on a second main side, which is opposite the first main side, of the membrane layer and extends laterally away from the membrane layer;
forming second spacers carrying the first and second support structures laterally next to the membrane in each case; and
removing the bonding material.

12. The method as claimed in claim 11, wherein providing the first wafer comprises producing a semiconductor layer comprising a monocrystalline material or comprising an amorphous material.

13. The method as claimed in claim 11, wherein providing the first wafer is performed such that the wafer is an SOI wafer, the membrane layer being a monocrystalline silicon layer of the SOI wafer which is separated from an SOI substrate of the SOI wafer by a buried oxide layer.

14. The method as claimed in claim 11, wherein providing the second wafer comprises producing a wafer comprising a readout circuit, at least part of the readout circuit being arranged within the substrate.

15. The method as claimed in claim 11, further comprising applying a first bonding layer to the patterned membrane layer, providing the second wafer being performed such that the second wafer comprises a second bonding layer, connecting the first and second wafers comprising bonding of the first bonding layer to the second bonding layer.
